(19) United States
(12) Patent Application Publication
(10) Pub. No.: US 2012/0112766 A1
(43) Pub. Date: May 10, 2012

(54) ELECTROMAGNETIC INDUCTION COORDINATE DETECTING SYSTEM AND METHOD THEREOF

(75) Inventors: CHUNG-WEN HSU, Kaohsiung City (TW); CHENG-LU LIU, HSIN-CHU CITY (TW)

(73) Assignee: WALTOP INTERNATIONAL CORPORATION, HSIN-CHU CITY (TW)

(21) Appl. No.: 13/163,615

(22) Filed: Jun. 17, 2011

(30) Foreign Application Priority Data
Nov. 9, 2010 (TW) 099138430

(51) Int. Cl. G01R 27/04

(52) U.S. Cl. 324/633

(57) ABSTRACT

An electromagnetic induction coordinate detecting method for detecting the trace of at least one electromagnetic pointing device on an electromagnetic sensor board is disclosed. The method includes the following steps: first, a delayed period for each electromagnetic pointing device is pre-determined. Then, whether a board-trigger signal from the electromagnetic sensor board is received is determined. If yes, the electromagnetic pointing device emits an electromagnetic signal after the delayed period. Finally, the electromagnetic sensor board calculates the coordinate and the pressure of each electromagnetic pointing device according to the received electromagnetic signal.

### CROSS-REFERENCE TO RELATED APPLICATIONS

The entire contents of Taiwan Patent Application No. 099138430, filed on Nov. 9, 2010, from which this application claims priority, are incorporated herein by reference.

### BACKGROUND OF THE INVENTION

1. Field of the Invention

The present invention generally relates to a coordinate detecting system and method thereof, and more particularly to an electromagnetic induction coordinate detecting system and method for supporting operations of multiple pointing devices.

2. Description of Related Art

Conventional electromagnetic induction coordinate detecting systems were designed with various frequency to resonate with the resonance circuits of a plurality of electromagnetic pointing devices. Therefore, multiple electromagnetic pointing devices could be operated in chorus on the electromagnetic induction coordinate detecting systems. However, it must increase hardware complexity to generate various frequency to control multiple electromagnetic pointing devices at the same time. For example, when using multiple electromagnetic pointing devices, in order to transmit data or signal between one specific electromagnetic pointing device and the electromagnetic induction coordinate detecting system, a corresponding hardware or circuit must be used to build signal communication with the specific electromagnetic pointing device, and it may increase hardware cost and complexity.

In view of the above drawback of conventional electromagnetic induction coordinate detecting systems, a need has arisen to propose an electromagnetic induction, coordinate detecting system and method to support operations of multiple electromagnetic pointing devices without increasing extra hardware cost and complexity.

### SUMMARY OF THE INVENTION

In view of the foregoing, it is an object of the embodiment of the present invention to provide an electromagnetic induction coordinate detecting system and method thereof to support operations of multiple electromagnetic pointing devices without increasing hardware cost and complexity.

According to one embodiment, an electromagnetic induction coordinate detecting system which includes an electromagnetic sensor board and at least one electromagnetic pointing device provided. The electromagnetic sensor board is configured to emit a board-trigger signal. The electromagnetic pointing device includes an oscillation unit, a monitoring unit, and a first control unit. The oscillation unit is configured to couple the received, board-trigger signal and emit a coupled-trigger signal. The monitoring unit is configured to generate an internal trigger signal. The first control unit is configured to control the oscillation unit to emit an electromagnetic signal for a signal emitting period, after a delayed period when receiving the internal trigger signal. Wherein, the oscillation unit is enabled after receiving the board-trigger signal.

Accordingly, the electromagnetic sensor board calculates the coordination and pressure of each electromagnetic pointing device according to the electromagnetic signal.

According to another embodiment, an electromagnetic induction, coordinate detecting method for detecting the trace of at least one electromagnetic pointing device on an electromagnetic sensor board is disclosed. The method includes the following steps: first, a delayed, period for each electromagnetic pointing device is pre-determined. Then, whether a board-trigger signal from the electromagnetic sensor board is received is determined. If yes, the electromagnetic pointing device emits an electromagnetic signal after the delayed period. If not, it proceeds to determine whether the board-trigger signal is received. Finally, the coordinate and the pressure of each electromagnetic pointing device are calculated according to the received electromagnetic signal.

### BRIEF DESCRIPTION OF THE DRAWINGS

FIG. 1 shows an operating situation of an electromagnetic induction coordinate detecting system according to one embodiment of the present invention;

FIG. 2 shows a block diagram illustrating an electromagnetic pointing device according to one embodiment of the present invention;

FIG. 3 shows a timing diagram of emitting signal of multiple electromagnetic pointing devices of FIG. 2;

FIG. 4 shows a block diagram illustrating an electromagnetic pointing device according to another embodiment of the present invention;

FIG. 5 shows a timing diagram of emitting signal of multiple electromagnetic pointing devices of FIG. 4;

FIG. 6 shows a timing diagram of electromagnetic signals emitted from multiple electromagnetic pointing devices after receiving trigger signal;

FIG. 7 shows a flow diagram illustrating a coordinate detecting method for an electromagnetic pointing device with battery according to one embodiment of the present invention; and

FIG. 8 shows a flow diagram illustrating a coordinate detecting method for an electromagnetic pointing device without battery according to one embodiment of the present invention.

### DETAILED DESCRIPTION OF THE INVENTION

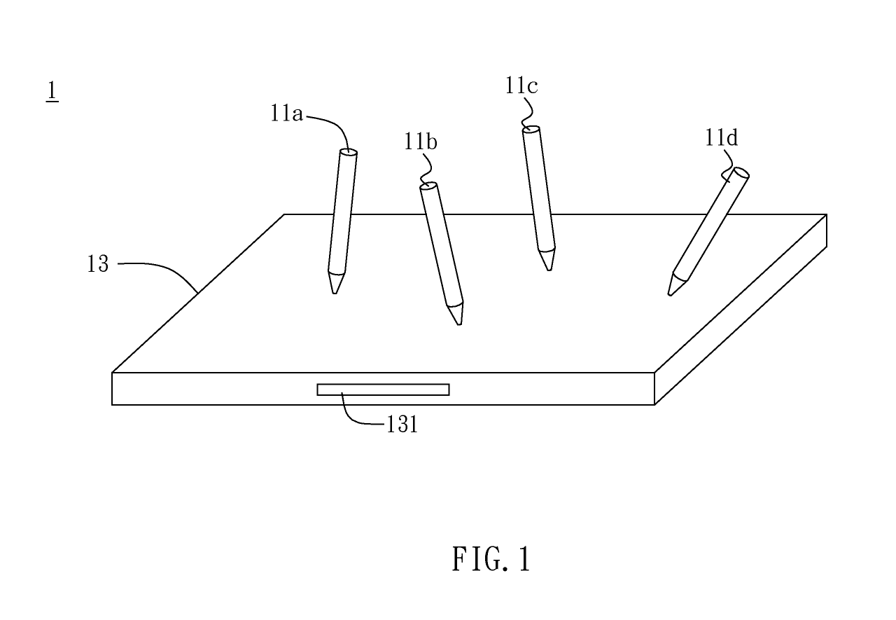

FIG. 1 shows an operating situation of an electromagnetic induction, coordinate detecting system according to one embodiment of the present invention. The electromagnetic induction coordinate detecting system 1 mainly includes an electromagnetic sensor board and at least one electromagnetic pointing device. One embodiment exemplifies four electromagnetic pointing devices 11a-11d in the present invention. The electromagnetic sensor board 13 emits a board-trigger signal periodically. A delayed period for each electromagnetic pointing device is pre-determined. When receiving the board-trigger signal, the electromagnetic pointing device responses an electromagnetic signal to the electromagnetic sensor board 13 after waiting for the pre-determined delayed period. In one embodiment of the present invention, the electromagnetic pointing devices 11a-11d are tied-in sale with the electromagnetic sensor board 13, the electromagnetic sensor board 13 has a control unit 131 to record the delayed period of each electromagnetic pointing device. Therefore, the electromagnetic sensor board 13 can recognize the electromagnetic pointing devices 11a-11d according to the time when receiving the electromagnetic signal, and calculate the coordinate and the pressure of the electromagnetic pointing devices 11a-11d. Specifically, the electromagnetic sensor board 13 may be a tablet and the electromagnetic pointing devices 11a-11d include an electromagnetic pen, electromagnetic stylus, electromagnetic puck, or electromagnetic mouse, but is not limited to this.

FIG. 9 shows a block diagram illustrating an electromagnetic pointing device according to one embodiment of the present invention. Take the electromagnetic pointing device 11a as example, which includes a control unit 102, a monitoring unit 104, an oscillation unit 106, a power management unit 108, and a power supply 110. The electromagnetic pointing device 11a uses the internal power supply 110 to supply voltage and electricity to every unit. More specifically, the power supply 110 may be, but is not limited, to, a battery.

The oscillation unit 1.06 includes an oscillation circuit, forming a resonance circuit with the inductance L, which is configured to resonate and couple the board-trigger signal from the electromagnetic sensor board 13. The coupled frequency is, but is not limited to, equal to or multiple of the frequency of the board-trigger signal emitted from the electromagnetic sensor board 13. The control unit 102 is configured to control when to response an electromagnetic signal from the oscillation unit 106. For example, the control unit 102 includes, but is not limited to, a microcontroller unit, a microprocessor, or any other control circuit.

The control unit 102 disables the oscillation unit. 106 in the beginning, therefore the electromagnetic pointing device 11a could not emit any electromagnetic signal to the electromagnetic sensor board 13. The electromagnetic sensor board. 13 in the present invention emits a board-trigger signal periodically. Once the electromagnetic pointing device 11a is in the proximity of the electromagnetic sensor board 13 and coupled the board-trigger signal, the oscillation unit 106 immediately resonates and couples the board-trigger signal and transfer a coupled-trigger signal to the monitoring unit 104. When receiving the coupled-trigger signal which is accumulated enough, the monitoring unit 104 transfers an internal trigger signal TS to the control unit 102. When receiving the internal trigger signal TS, the control unit 102 must wait during the pre-determined delayed period and enables the oscillation unit 106, and then controls the oscillation unit 106 to emit an electromagnetic signal to the electromagnetic sensor board 13. The electromagnetic signal is usually emitted for a period (signal emitting period.), accordingly, the electromagnetic sensor board 13 calculates the coordinate and the pressure of the electromagnetic pointing device 11a according to the electromagnetic signal.

It is noted that the monitoring unit 104, which is used to receive the coupled-trigger signal, may be integrated, into the control unit 102, i.e., the control unit 102 receives the trigger signal from the electromagnetic sensor board 13. After the intensity of the trigger signal is accumulated enough, the control unit 102 controls the oscillation unit 106 to emit the electromagnetic signal to the electromagnetic sensor board 13 in accordance with the pre-setting time.

The power management unit 108 is configured to stabilize the voltage provided from the power supply 110 to be the regulated power supply. Specifically, the power management unit 108 includes a regulation circuit. The regulated power supply from the power management unit 108 supplies voltage and electricity to the control unit 102, the monitoring unit 104 and the oscillation unit 106. After using the electromagnetic pointing device for a while, the consumption of the battery electricity causes to decrease the voltage gradually. Therefore the power management unit 108 controls the power supply 110 to provide stable voltage to the electromagnetic pointing device.

The electromagnetic pointing devices 11a-11d has an internal power supply in the present invention. When the electromagnetic pointing devices 11a-11d is in the proximity of the electromagnetic sensor board 13 simultaneously and receive the board-trigger signal, the electromagnetic pointing devices 11a-11d emit the electromagnetic signals to the electromagnetic sensor board 13 in different time according to the corresponding pre-determined delayed periods, respectively. Specifically, the electromagnetic pointing devices 11a-11d emit the electromagnetic signals in sequence, i.e., the time when the control unit 102 of all electromagnetic pointing devices 11a-11d enables itself oscillation unit 106 are different. The control unit 131 and signal processing circuit (not shown) of electromagnetic sensor board 13 can recognize all the electromagnetic pointing devices 11a-11d according to when to receive the electromagnetic signals from the electromagnetic pointing devices 11a-11d. It can display the coordinates and moving traces of multiple electromagnetic pointing devices 11a-11d substantially simultaneously. Therefore, even if using a single frequency, the electromagnetic induction coordinate detecting system 1 achieves to operate multiple pointing devices 11a-11d simultaneously.

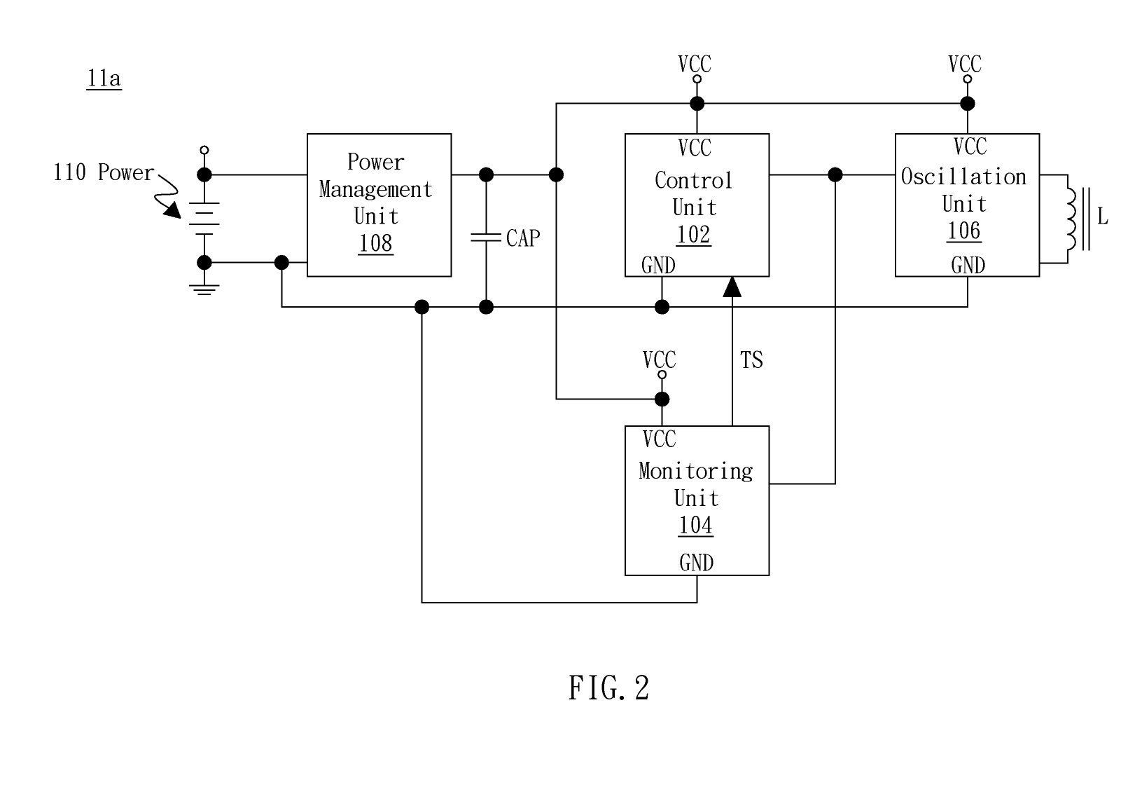

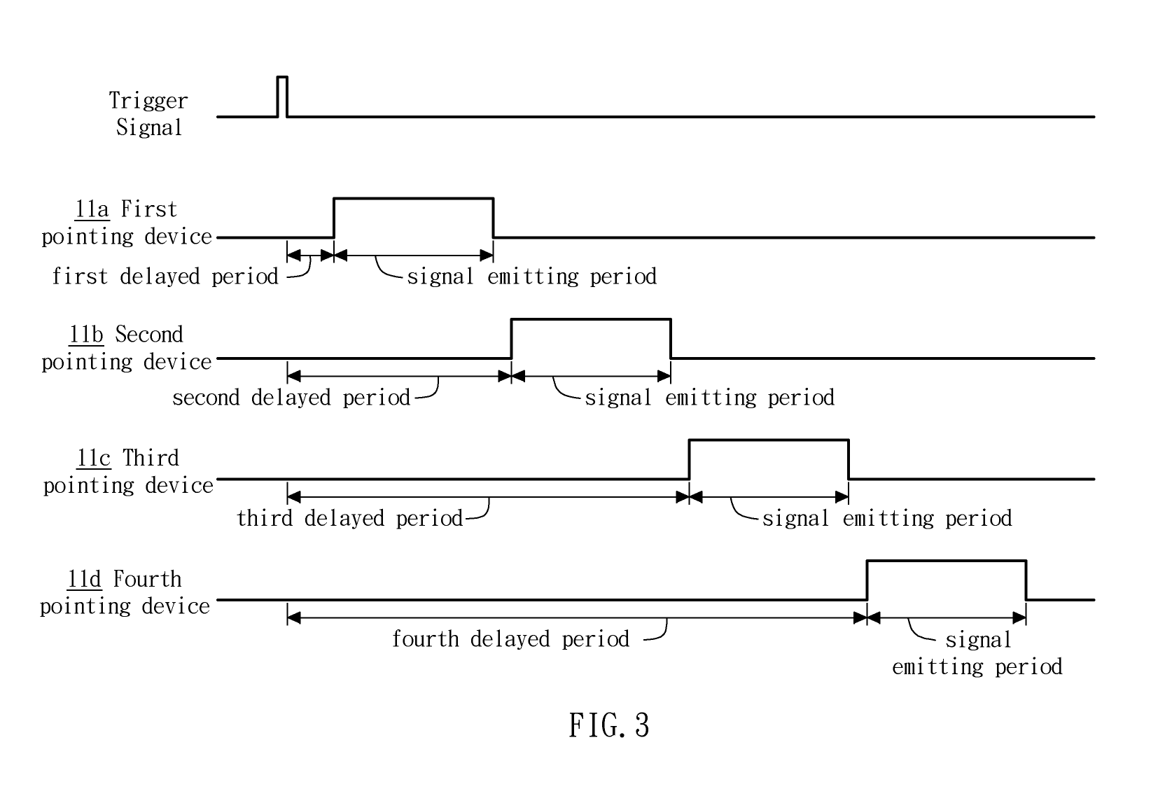

FIG. 3 shows a timing diagram of emitting signal of multiple electromagnetic pointing devices of FIG. 2. When the electromagnetic pointing devices 11a-11d receive the board-trigger signal from the electromagnetic sensor board 13, each monitoring unit 104 of the electromagnetic pointing devices 11a-11d receives the coupled-trigger signal from the oscillation unit 106, and transfers the internal trigger signal TS to the control unit 102, as shown in FIG. 3. When receiving the internal trigger signal TS, the control unit 102 of the first electromagnetic pointing device 11a controls itself oscillation unit 106 to emit the electromagnetic signal after waiting for a pre-determined first delayed period, such as 100 μs. The electromagnetic signal is emitted continuously for a signal emitting period, such as 300 μs. Sequentially, the control unit 102 of the second electromagnetic pointing device 11b controls itself oscillation unit 106 to emit the electromagnetic signal after waiting for a pre-determined second delayed period, such as the sum of the first delayed period and the signal emitting period, of the first electromagnetic pointing device 11a. The electromagnetic signal is also emitted continuously for a signal emitting period, such as 300 μs. Similarly, the control unit 102 of the third electromagnetic pointing device 11ccontrols itself oscillation unit 106 to emit the electromagnetic signal after waiting for a pre-determined third delayed period, such as the sum of the first delayed period, the signal emitting period of the first electromagnetic pointing device 11a and the signal emitting period of the second electromagnetic pointing device 11b (i.e., 100 μs+300 μs*2). The electromagnetic signal is also emitted continuously for a the signal emitting period, such as 300 μs. The control unit 102 of the fourth electromagnetic pointing device 11d controls itself oscillation unit 106 to emit the electromagnetic signal after waiting for a pre-determined fourth delayed period, such as the sum of the first delayed period and the signal emitting periods of the electromagnetic pointing devices 11a-11c (i.e., 100 μs+300 μs*3). The electromagnetic signal is also emitted continuously for a signal emitting period, such as 300 μs.

Actually, to avoid interference from the signals of different electromagnetic pointing devices 11a-11d, it may reserve a time slot buffer between the end time, when one electromagnetic pointing device emits signal, and the start time, when the other electromagnetic pointing device emits signal. The frequency of the board-trigger signal is constant, and the board-trigger signal is emitted periodically from the electromagnetic sensor board 13. If the electromagnetic pointing devices 11a-11d is in the proximity of the electromagnetic sensor board 13 for a while, all the electromagnetic pointing devices can induce the board-trigger signal respectively. The trigger signal TS in FIG. 2 means the internal trigger signal of the electromagnetic pointing devices 11a-11d.

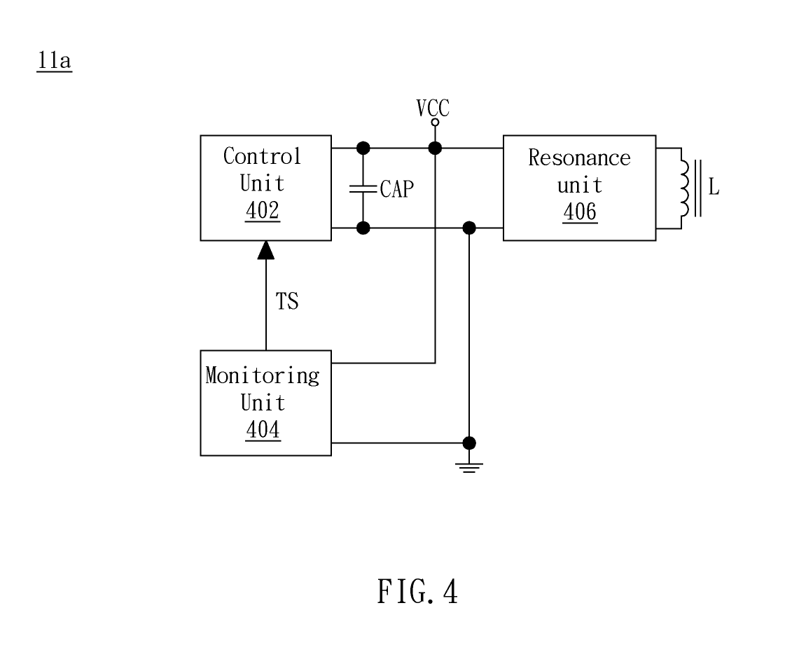

FIG. 4 shows a block diagram illustrating an electromagnetic pointing device according to another embodiment of the present invention. The electromagnetic pointing devices 11a-11d are the electromagnetic pens without internal power supply in the present invention, compared with the architecture of FIG. 2, which omit the power management unit 108 and the power supply 110. Besides, the most different from FIG. 2 is that the electromagnetic sensor board 13 emits the board-trigger signal continuously during an oscillation charging period. The electromagnetic pointing devices 11a-11d resonate and couple the received board-trigger signal during the oscillation charging period, and then store electricity into the capacitor, CAP, to supply for the control unit 402, the resonance unit 406, and the monitoring unit 404.

After charging enough, such as during the oscillation charging period, the resonance unit 406 transfers the coupled-trigger signal, which makes the monitoring unit 404 generate the internal trigger signal TS to the control unit 402. When receiving the internal trigger signal TS, the control unit 402 of each electromagnetic pointing device controls the resonance unit 406 to response the electromagnetic signal to the electromagnetic sensor board 13 according to the pre-determined delayed period. Accordingly, the electromagnetic sensor board 13 calculates the coordinate and the pressure of each electromagnetic pointing device according to the electromagnetic signal.

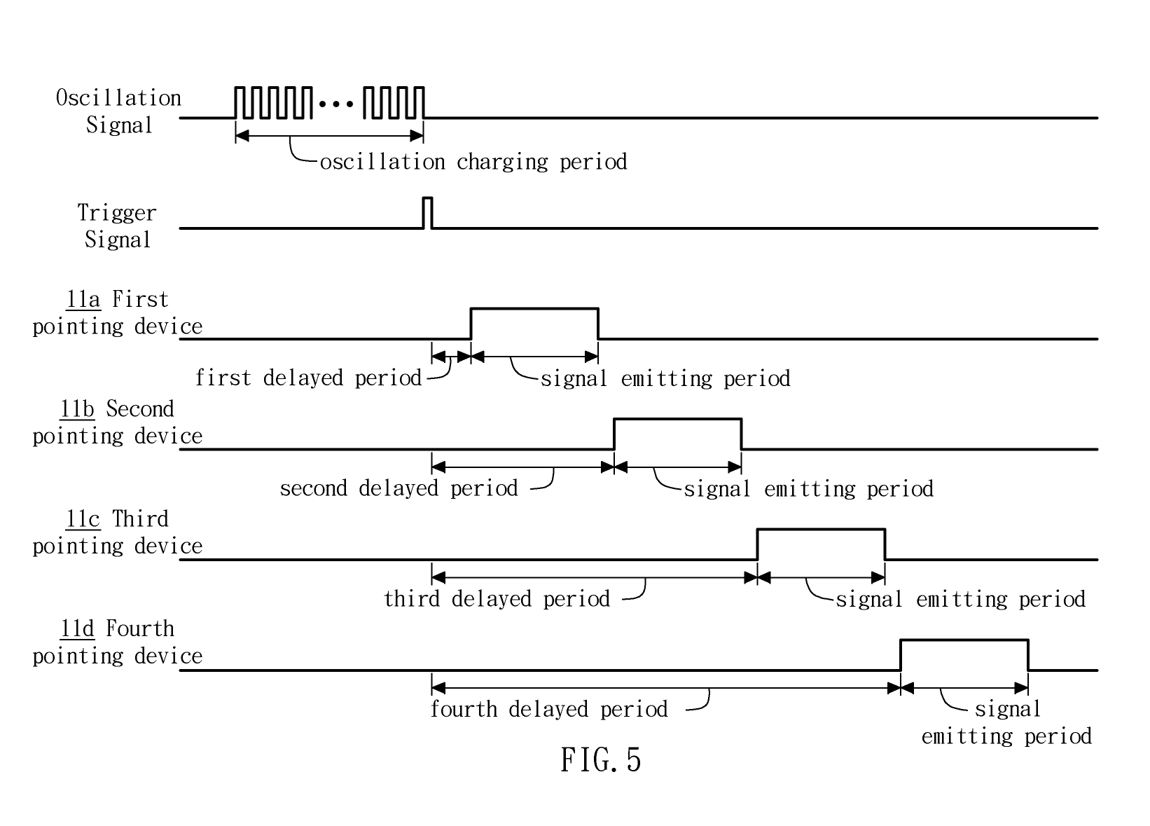

FIG. 5 shows a timing diagram of emitting signal of multiple electromagnetic pointing devices of FIG. 4. When the electromagnetic pointing devices 11a-11d receive the board-trigger signal from the electromagnetic sensor board 13, each resonance unit 406 of the electromagnetic pointing devices 11a-11d starts to resonate and charge, as shown in FIG. 5. The period of charging is the oscillation charging period, such as 20-30 cycles, and the frequency of it is 375 Hz, but is not limited to this. After finishing charging, the monitoring unit 404 transfers the internal trigger signal TS to the control unit 402. Each electromagnetic pointing device then emits the electromagnetic signal to the electromagnetic sensor board 13 according to the pre-determined delayed period. The control unit 131 of the electromagnetic sensor board 13 can recognize the electromagnetic pointing devices 11a-11d according to the time when receiving the electromagnetic signal, and calculate the coordinate and the pressure of each electromagnetic pointing device. The operations and functions in the present embodiment are similar to that in FIG. 9.

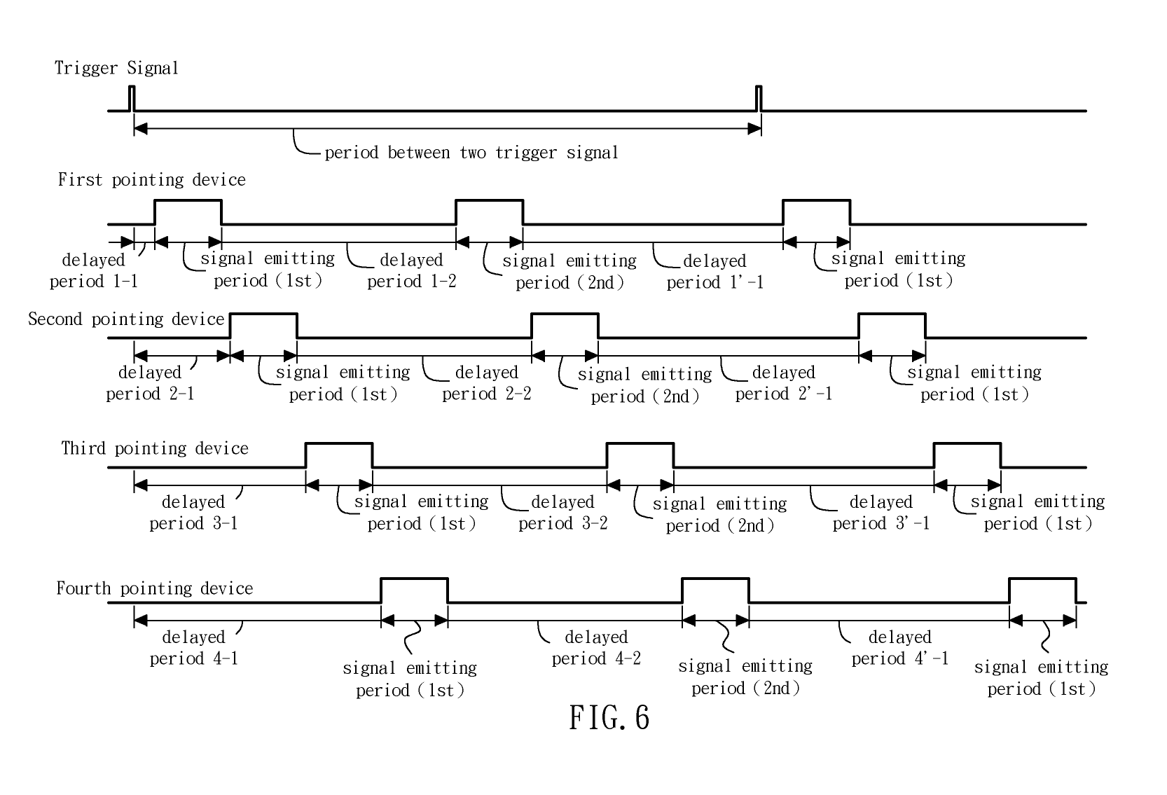

FIG. 6 shows a timing diagram of electromagnetic signals emitted from multiple electromagnetic pointing devices after receiving trigger signal. The timing diagram of FIG, 6 is suitable for the electromagnetic pointing devices 11a-11d in FIG. 2 and FIG. 4. During the time interval when the monitoring unit 104 transfers two internal trigger signals TS to the control unit 102, each electromagnetic pointing device emits the electromagnetic signal twice in sequence. The emitting duration of the internal trigger signal TS can be adjusted, and so does the number of times of emitting the electromagnetic signal.

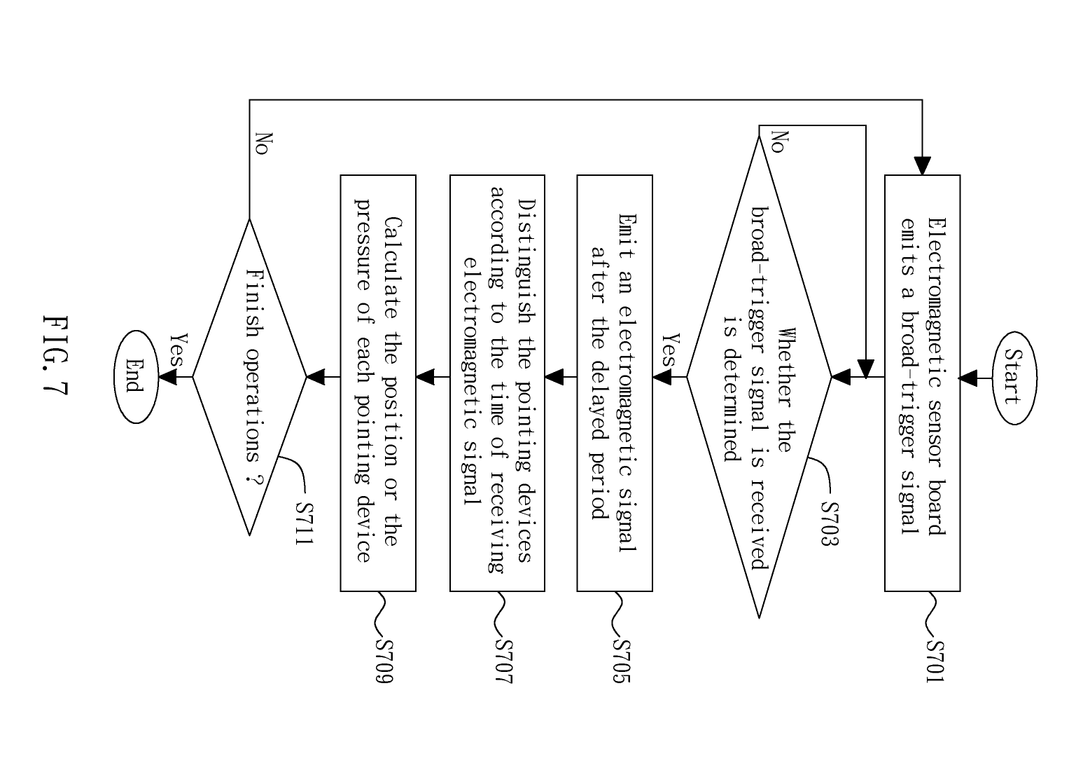

Finally, FIG. 7 shows a flow diagram illustrating a coordinate detecting method for an electromagnetic pointing device with battery according to one embodiment of the present invention. The method includes the following steps.

Firstly, the electromagnetic sensor board 13 emits the board-trigger signal periodically in step S701. When the electromagnetic pointing device(s) 11a-11d is in the proximity of the electromagnetic sensor board 13, whether the board-trigger signal is received is determined in step S703. If not, keep on detecting whether the board-trigger signal is received. If receiving the board-trigger signal, the electromagnetic pointing devices 11a-11d emit the electromagnetic signal after the pre-determined delayed period in step S705.

Then, in step S707, the electromagnetic sensor board 13 recognizes the electromagnetic pointing devices 11a-11d according to the time when receiving the electromagnetic signal, and calculates the coordinate and the pressure of the electromagnetic pointing devices 11a-11d in step S709.

Finally, the control unit 131 of the electromagnetic sensor board 13 determines whether it finishes operations, such as turning off the system 1, in step S711. If not, back to step S701, the electromagnetic sensor board 13 emits new board-trigger signal, and the above steps are repeated.

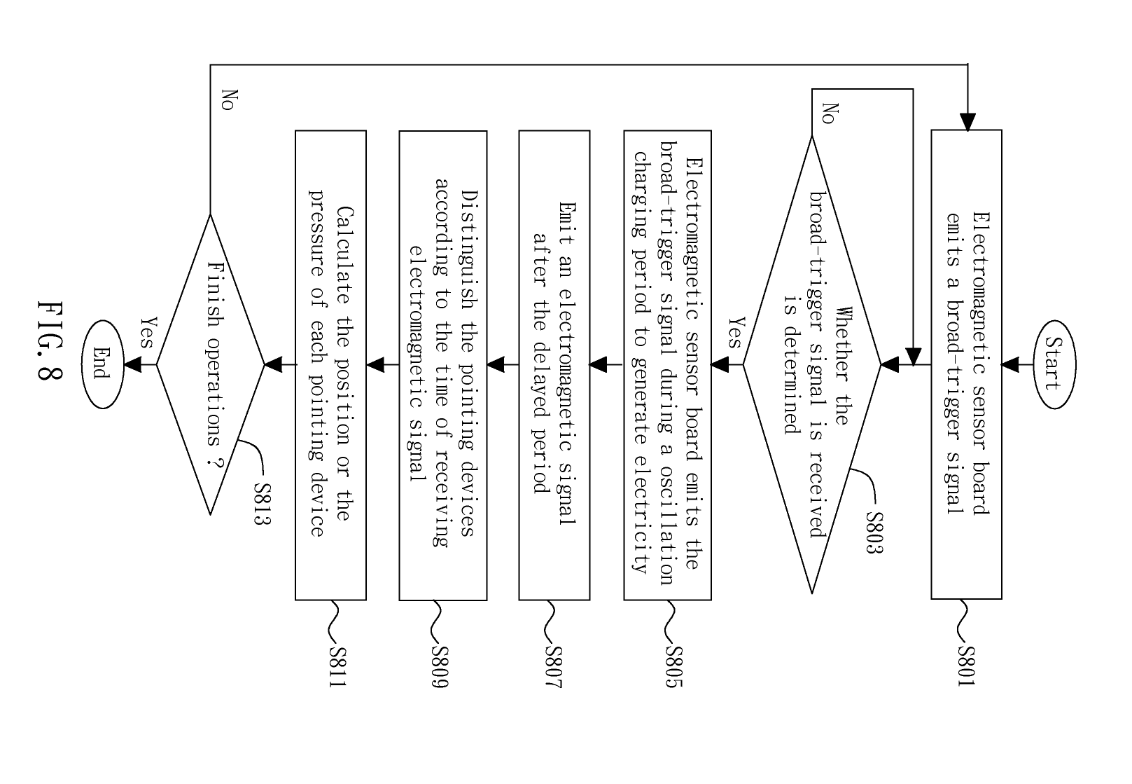

FIG. 8 shows a flow diagram illustrating a coordinate detecting method for an electromagnetic pointing device without battery according to one embodiment of the present invention. The operating flow paths of FIG. 7 and FIG. 8 are similar. It is noted that after determining the electromagnetic pointing devices 11a-11d receive the board-trigger signal emitted from the electromagnetic sensor board 13 (in step S803), the electromagnetic sensor board 13 must emit the board-trigger signal continuously during the oscillation charging period to generate electricity by resonating and coupling with the resonance unit 406 in step S805. After charging enough, the electromagnetic pointing devices 11a-11d will be controlled to emit the electromagnetic signals according to the pre-determined delayed period. The steps hereinafter are similar to the steps in FIG. 7.

According to the above embodiment, the electromagnetic induction coordinate detecting system and method thereof, provided in the present invention, controls multiple electromagnetic pointing devices which receive the board-trigger signal emit the electromagnetic signal in sequence, and the electromagnetic sensor board 13 then recognizes and calculates the coordinate and the pressure of the electromagnetic pointing devices 11a-11d, respectively. It realizes the electromagnetic induction coordinate detecting system for supporting operations of multiple electromagnetic pointing devices.

Although specific embodiments have been illustrated and described, it will be appreciated by those skilled in the art that various modifications may be made without departing from the scope of the present invention, which is intended to he limited solely by the appended claims.

What is claimed is:

1. An electromagnetic induction coordinate detecting system, comprising:
an electromagnetic sensor board configured to emit a board-trigger signal; and
at least one electromagnetic pointing device comprising:
an oscillation unit, configured to resonate and receive the board-trigger signal to emit a coupled-trigger signal;
a monitoring unit, configured to transfer an internal trigger signal according to the coupled-trigger signal; and
a first control unit, configured to control the oscillation unit to emit an electromagnetic signal for a signal emitting period after a delayed period when receiving the internal trigger signal;
wherein, the oscillation unit is enabled after receiving the internal trigger signal, the electromagnetic sensor board calculates the coordinate and the pressure of the electromagnetic pointing device according to the electromagnetic signal.

2. The system of claim 1, wherein the electromagnetic pointing device further comprises a power supply, configured to supply voltage and electricity for the first control unit, the oscillation unit, and the monitoring unit.

3. The system of claim 2, wherein the electromagnetic pointing device further comprises a power management unit comprising a regulation circuit, configured to stabilize the voltage provided from the power supply to be the regulated power supply.

4. The system of claim 1, wherein the electromagnetic sensor board emits the board-trigger signal continuously during an oscillation charging period, and the oscillation unit resonates and couples the received board-trigger signal during the oscillation charging period, and then stores electricity to supply the first control unit, the oscillation unit, and the monitoring unit.

5. The system of claim 4, wherein the oscillation unit emits the coupled-trigger signal after the oscillation charging period to make the monitoring unit generate the internal trigger signal.

6. The system of claim 4, wherein the electromagnetic pointing device is plural, and the delayed period of one electromagnetic pointing device is the sum of the delayed period of another electromagnetic pointing device and the signal emitting period.

7. The system of claim 6, wherein the electromagnetic sensor board comprises a second control unit, configured to recognize the electromagnetic pointing devices according to the electromagnetic signals which are emitted from the electromagnetic pointing devices.

8. The system of claim. 2, wherein the board-trigger signal is emitted periodically, and the first control unit controls the oscillation unit to emit multiple electromagnetic signals between two continuous board-trigger signals.

9. The system of claim 2, wherein the electromagnetic pointing device is plural, and the delayed period, of one electromagnetic pointing device is the sum of the delayed period, of another electromagnetic pointing device and the signal emitting period.

10. The system of claim 9, wherein the electromagnetic sensor board comprises a second control unit, configured to recognize the electromagnetic pointing devices according to the electromagnetic signals which are emitted from the electromagnetic pointing devices.

11. The system of claim. 10, wherein the first and second control unit comprises a microcontroller unit, a microprocessor, or a control circuit.

12. The system of claim 2, wherein the power supply comprises a battery.

13. An electromagnetic induction, coordinate detecting method for detecting the trace of at least one electromagnetic pointing device on an electromagnetic sensor board, and the method comprising:
pre-determining a delayed period for each electromagnetic pointing device;
determining whether a board-trigger signal from the electromagnetic sensor board is received, or not;
if yes, the electromagnetic pointing device emits an electromagnetic signal after the delayed period;
if not, keep on detecting whether the board-trigger signal is received; and
calculating the coordinate and the pressure of the electromagnetic pointing device according to the received electromagnetic signal.

14. The method of claim 13, wherein the electromagnetic pointing device emits the electromagnetic signal after the delayed period continuously during a signal emitting period.

15. The method of claim 14, wherein the electromagnetic sensor board emits the board-trigger signal continuously during an oscillation charging period to generate electricity.

16. The method of claim 15, wherein the electromagnetic pointing device emits the electromagnetic signal after the sum of the oscillation charging period and the delayed period.

17. The method of claim 14, wherein the board-trigger signal is emitted periodically, and the multiple electromagnetic signals are emitted between two continuous board-trigger signals.

18. The method of claim 17, wherein the electromagnetic pointing device is plural, and the delayed period of one electromagnetic pointing device is the sum of the delayed period of another electromagnetic pointing device and the signal emitting period.

19. The method of claim 17, further comprising:
recognizing the electromagnetic pointing devices according to the delayed period of the electromagnetic signal which is emitted by the electromagnetic pointing devices.
